(19) United States
(12) Patent Application Publication
(10) Pub. No.: US 2025/0297354 A1
(43) Pub. Date: Sep. 25, 2025

(54) DEPOSITION MASK AND METHOD FOR FABRICATING THE SAME

(71) Applicant: Samsung Display Co., LTD., Yongin-si (KR)

(72) Inventors: Jeong Kuk KIM, Yongin-si (KR); Ji Hyun JUNG, Yongin-si (KR); Sung Won CHO, Yongin-si (KR); Jun Ho JO, Yongin-si (KR)

(21) Appl. No.: 18/943,332

(22) Filed: Nov. 11, 2024

(30) Foreign Application Priority Data
Mar. 19, 2024 (KR) 10-2024-0037537

(51) Int. Cl. C23C 14/04

(52) U.S. Cl. CPC C23C 14/042

(57) ABSTRACT

There is provided a deposition mask. The deposition mask includes a mask substrate comprising a plurality of cell areas and a cell peripheral area surrounding the plurality of cell areas; a mask membrane overlapping with the cell areas of the mask substrate; and a mask frame overlapping with the cell peripheral area of the mask substrate, wherein the mask membrane comprises a mask shadow defining a pixel opening, wherein the mask frame comprises a first mask inorganic layer on the mask substrate, and a second mask inorganic layer on the first mask inorganic layer, and wherein the first mask inorganic layer and the second mask inorganic layer are formed in a certain pattern up to an edge of the mask substrate.

This application claims priority from Korean Patent Application No. 10-2024-0037537, filed on Mar. 19, 2024 in the Korean Intellectual Property Office, and all the benefits accruing therefrom under 35 U.S.C. 119, the contents of which in its entirety are herein incorporated by reference.

### BACKGROUND

### 1. Field of the Disclosure

The present disclosure relates to a deposition mask and a method for fabricating the same.

### 2. Description of the Related Art

A wearable device is being developed which is in the form of glasses or a helmet and forms a focus at a location close to the user's eyes. For example, a wearable device may be a head mounted display (HMD) device or an AR glass. Such a wearable device provides a user with an augmented reality (hereinafter referred to as “AR”) screen or a virtual reality (hereinafter referred to as “VR”) screen.

A wearable device such as a HMD device and AR glasses require display specifications of at least 2,000 PPI (pixels per inch) to allow users to use it for a long time without dizziness. To this end, organic light-emitting diode on silicon (OLEDoS) technology is emerging, which is high-resolution small organic light-emitting element display device. The OLEDoS is a technology for disposing organic light-emitting diodes (OLEDs) on a semiconductor wafer substrate on which a complementary metal oxide semiconductor (CMOS) is disposed.

### SUMMARY

Aspects of the present disclosure provide a silicon deposition mask that can fabricate a high-resolution display panel and a method for fabricating the same.

Aspects of the present disclosure provide a deposition mask that improves the adhesion between a high-resolution display panel and a deposition mask by solving the issue of warpage of a mask inorganic layer included in a mask frame.

It should be noted that objects of the present disclosure are not limited to the above-mentioned object; and other objects of the present disclosure will be apparent to those skilled in the art from the following descriptions.

The details of one or more embodiments of the subject matter described in this specification are set forth in the accompanying drawings and the description below.

In an embodiment of the disclosure, a deposition mask includes a mask substrate comprising a plurality of cell areas and a cell peripheral area surrounding the plurality of cell areas; a mask membrane overlapping with the cell areas of the mask substrate; and a mask frame overlapping with the cell peripheral area of the mask substrate, wherein the mask membrane comprises a mask shadow defining a pixel opening, wherein the mask frame comprises a first mask inorganic layer on the mask substrate, and a second mask inorganic layer on the first mask inorganic layer, and wherein the first mask inorganic layer and the second mask inorganic layer are formed in a certain pattern up to an edge of the mask substrate.

In an embodiment, the first mask inorganic layer and the second mask inorganic layer may do not overlap with the cell areas, and wherein the second mask inorganic layer may comprise a same material as the mask shadow.

In an embodiment, the pixel opening may be a through hole, and wherein the second mask inorganic layer may be spaced apart from the mask shadow with the pixel opening therebetween.

In an embodiment, the mask substrate may comprise silicon, and wherein the mask substrate has a circular shape when viewed from top.

In an embodiment, the first mask inorganic layer and the second mask inorganic layer may comprise an inorganic insulating material, and wherein the first mask inorganic layer and the second mask inorganic layer comprise different materials.

In an embodiment, the first mask inorganic layer may comprise silicon oxide, and the second mask inorganic layer comprises silicon nitride.

In an embodiment, the mask frame may comprise a third mask inorganic layer located on the mask substrate on an opposite side of the first mask inorganic layer; and a fourth mask inorganic layer may locate on the third mask inorganic layer.

In an embodiment, the third mask inorganic layer may be made of a same material as the first mask inorganic layer, and the fourth mask inorganic layer may be made of a same material as the second mask inorganic layer.

In an embodiment, a height of the first mask inorganic layer may be equal to a height of the third mask inorganic layer, and a height of the second mask inorganic layer is equal to a height of the fourth mask inorganic layer.

In an embodiment, the mask substrate may comprise a first side surface facing the cell area, wherein the first mask inorganic layer may comprise a second side surface facing the cell area, and wherein the first side surface and the second side surface may be located on a same line.

In an embodiment, the second mask inorganic layer may comprise a third side surface facing the cell area, and the third side surface may be located on the same line as the first side surface and the second side surface.

In an embodiment, the third side surface may be spaced apart from the mask shadow with the pixel opening therebetween.

In an embodiment, the second side surface may be located between the first side surface and the third side surface.

In an embodiment, the mask frame may define a mask opening when viewed from top, wherein the membrane may overlap with the mask opening when viewed from the top, and wherein the mask frame may completely surround the membrane when viewed from the top.

A method for fabricating a deposition mask, the method includes forming a first inorganic material layer on a mask substrate comprising a plurality of cell areas and a cell peripheral area surrounding the plurality of cell areas; forming a second inorganic material layer on the first inorganic material layer; forming a mask membrane by patterning the second inorganic material layer located on an upper surface of the mask substrate; forming a mask opening by removing the first inorganic material layer and the second inorganic material layer located on a lower surface of the mask substrate; and removing a portion of the mask substrate overlapping with the mask opening and the first inorganic material layer located on the upper surface of the mask substrate.

In an embodiment, the forming the first inorganic material layer may comprise forming the first inorganic material layer simultaneously on the upper and lower surfaces of the mask substrate.

In an embodiment, the forming the second inorganic material layer may comprise forming the second inorganic material layer simultaneously on the upper and lower surfaces of the mask substrate.

In an embodiment, the first inorganic material layer and the second inorganic material layer may comprise different materials.

In an embodiment, a side surface of the first inorganic material layer and a side surface of the second inorganic material layer may be located on a same line extended from a side surface of the patterned mask substrate.

In an embodiment, the first inorganic material layer and the second inorganic material layer may be patterned up to an edge of the mask substrate.

In an embodiment of the disclosure, an electronic device includes a display device including a display panel formed using a deposition mask; a mask substrate comprising a plurality of cell areas and a cell peripheral area surrounding the plurality of cell areas; a mask membrane overlapping with the cell areas of the mask substrate; and a mask frame overlapping with the cell peripheral area of the mask substrate, wherein the mask membrane comprises a mask shadow defining a pixel opening, wherein the mask frame comprises a first mask inorganic layer on the mask substrate, and a second mask inorganic layer on the first mask inorganic layer, and wherein the first mask inorganic layer and the second mask inorganic layer are formed in a certain pattern up to an edge of the mask substrate.

According to embodiments of the present disclosure, it is possible to provide a deposition mask for fabricating a high-resolution display panel by forming a mask inorganic layer and a mask membrane on a mask substrate. In addition, according to an embodiment of the present disclosure, a deposition mask can solve the issue of warpage of a mask inorganic layer by patterning the mask inorganic layer to be located on the same line as the edge of a mask substrate, thereby enhancing the adhesion between a high-resolution display panel and the deposition mask.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing a head-mounted electronic device according to an embodiment of the present disclosure.

FIG. 2 is an exploded perspective view showing an example of the head-mounted electronic device of FIG. 1.

FIG. 3 is a perspective view showing a head-mounted electronic device according to an embodiment of the present disclosure.

FIG. 4 is an exploded, perspective view showing a display device according to an embodiment of the present disclosure.

FIG. 5 is a cross-sectional view showing an example of a part of a display panel according to an embodiment of the present disclosure.

FIG. 6 is a plan view of a mask according to an embodiment of the present disclosure.

FIG. 7 is an enlarged plan view of area A of FIG. 6.

FIG. 8 is a cross-sectional view taken along line X1-X1′ of FIG. 7.

FIG. 9 is an enlarged cross-sectional view of the mask frame and structures around the mask frame of FIG. 8.

FIG. 10 is a flowchart for illustrating a method of fabricating a mask according to an embodiment of the present disclosure.

FIGS. 11 to 20 are cross-sectional views for illustrating processing steps of the method of fabricating a mask according to an embodiment of the present disclosure.

### DETAILED DESCRIPTION OF THE EMBODIMENTS

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings.

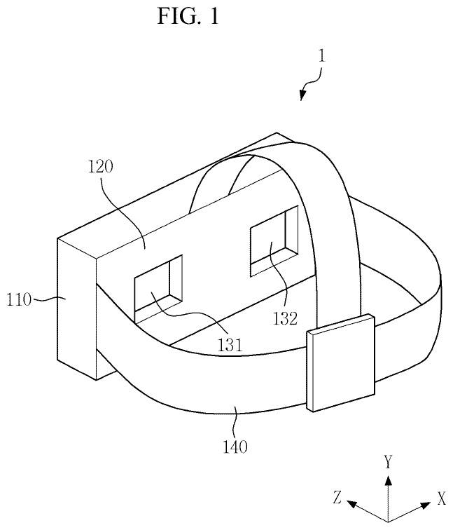

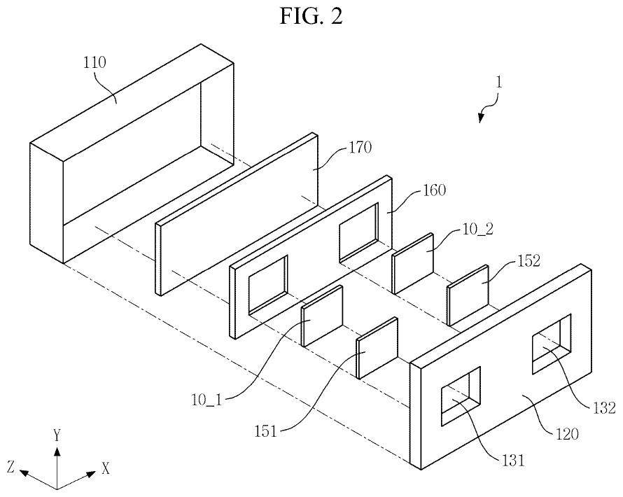

FIG. 1 is a perspective view showing a head-mounted electronic device 1 according to an embodiment. FIG. 2 is an exploded perspective view of an example of the head-mounted electronic device of FIG. 1.

Referring to FIGS. 1 and 2, the head-mounted electronic device 1 according to an embodiment includes a display device housing 110, a housing cover 120, a first eyepiece 131, a second eyepiece 132, a head strap band 140, a first display device 10_1, a second display device 10_2, a middle frame 160, a first optical member 151, a second optical member 152, a control circuit board 170, and a connector.

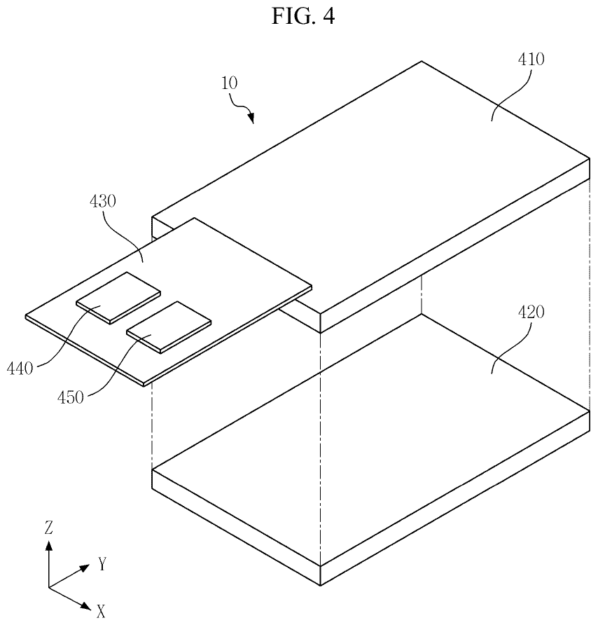

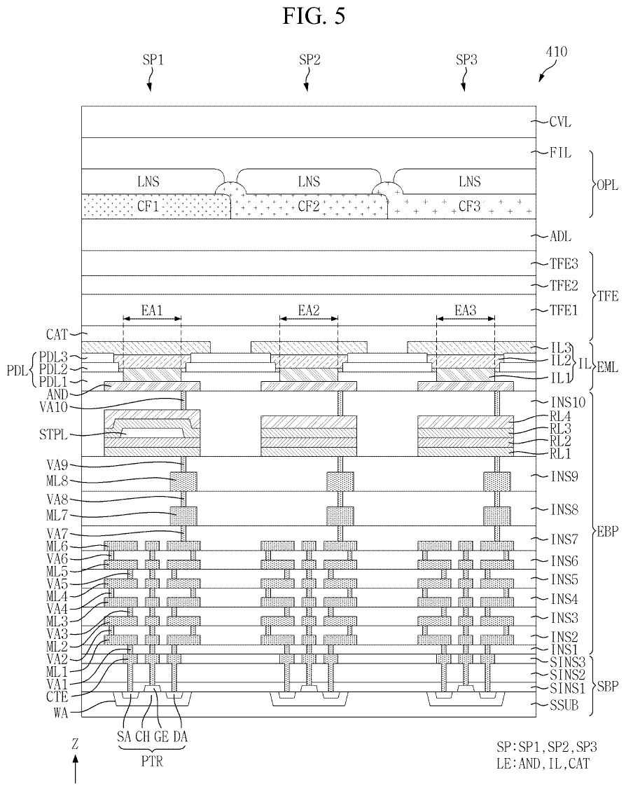

The first display device 10_1 provides images to a user's left eye, and the second display device 10_2 provides images to the user's right eye. Each of the first display device 10_1 and the second display device 10_2 is substantially identical to the display device 10 described with reference to FIGS. 4 and 5. Therefore, descriptions of the first display device 10_1 and the second display device 10_2 will be replaced with descriptions referring to FIGS. 4 and 5.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 serves to support and fix the first display device 10_1, the second display device 10_2 and the control circuit board 170.

The control circuit board 170 may be disposed between the middle frame 160 and the display device housing 110. The control circuit board 170 may be connected to the first display device 10_1 and the second display device 10_2 through a connector. The control circuit board 170 may convert an image source input from the outside into digital video data (DATA) and may transmit the digital video data (DATA) to the first display device 10_1 and the second display device 10_2 through the connector.

The control circuit board 170 may transmit digital video data (DATA) associated with a left eye image optimized for the user's left eye to the first display device 10_1, and may transmit digital video data (DATA) associated with a right eye image optimized for the user's right eye to the second display device 10_2. Alternatively, the control circuit board 170 may transmit the same digital video data (DATA) to the first display device 10_1 and the second display device 10_2.

The display device housing 110 accommodates the first display device 10_1, the second display device 10_2, the middle frame 160, the first optical member 151, the second optical member 152, the control circuit board 170, and the connector. The housing cover 120 is disposed to cover the open face of the housing 110. The housing cover 120 may include the first eyepiece 131 where the user's left eye is placed, and the second eyepiece 132 where the user's right eye is placed. Although the first eyepiece 131 and the second eyepiece 132 are separately disposed in the example shown in FIGS. 1 and 2, the embodiments of the present disclosure are not limited thereto. The first eyepiece 131 and the second eyepiece 132 may be combined into a single element.

The first eyepiece 131 may be aligned with the first display device 10_1 and the first optical member 151, and the second eyepiece 132 may be aligned with the second display device 10_2 and the second optical member 152. Therefore, a user may see virtual images of images on the first display device 10_1 magnified by the first optical member 151 through the first eyepiece 131, and virtual images of images on the second display device 10_2 magnified by the second optical member 152 through the second eyepiece 132.

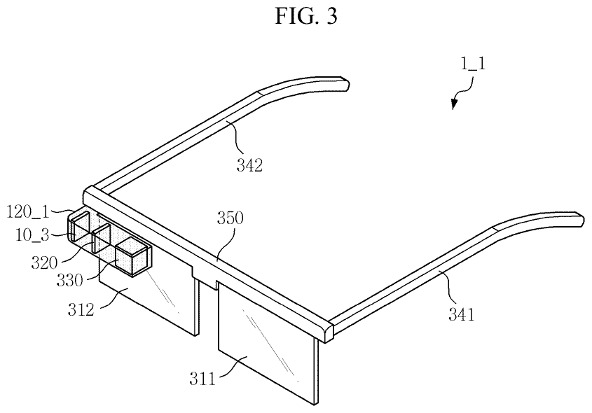

The head strap band 140 fixes the housing 110 to the user's head so that the first eyepiece 131 and the second eyepiece 132 of the housing cover 120 remain in line with the user's left and right eyes, respectively. By implementing a light and small display device housing 110, the head-mounted electronic device 1 may include an eyeglasses frame as shown in FIG. 3 instead of a head strap band 140.

In addition, the head-mounted electronic device 1 may further include a battery for supplying power, an external memory slot for inserting an external memory, and an external connection port and a wireless communication module for receiving an image source. The external connection port may be a USB (universe serial bus) terminal, a display port, or an HDMI (high-definition multimedia interface) terminal. The wireless communication module may be a 5G communication module, a 4G communication module, a Wi-Fi module, or a Bluetooth module.

FIG. 3 is a perspective view showing a head-mounted electronic device 1_1 according to an embodiment.

Referring to FIG. 3, the head-mounted electronic device 1_1 according to the embodiment may be a glasses-type display device with a light and small display device housing 120_1. The head-mounted electronic device 1_1 according to the embodiment may include a display device 10_3, a left-eye lens 311, a right-eye lens 312, a support frame 350, eyeglass temples 341 and 342, an optical member 320, an optical path conversion member 330, and a display device housing 120_1.

The display device 10_3 shown in FIG. 3 is substantially identical to the display device 10 described with reference to FIGS. 4 and 5. Therefore, descriptions of the first display device 10_1 and the second display device 10_2 will be replaced with descriptions referring to FIGS. 4 and 5.

The display device housing 120_1 may include the display device 10_3, the optical member 320, and the optical path conversion member 330. The images displayed on the display device 10_3 may be enlarged by the optical member 320, and the optical path of the images are converted by the optical path conversion member 330 to be provided to the user's right eye through the right eye lens 312. As a result, the user can see, with the right eye, augmented reality images that combine virtual images displayed on the display device 10_3 and real world images viewed through the right eye lens 312.

Although the display device housing 120_1 is disposed at the right end of the support frame 350 in the example shown in FIG. 3, the embodiments of the present disclosure are not limited thereto. For example, the display device housing 120_1 may be disposed at the left end of the support frame 350. In such case, images displayed on the display device 10_3 may be provided to the user's left eye. Alternatively, the display device housing 120_1 may be disposed at both the left and right ends of the support frame 350, respectively. In such case, the user can watch images displayed on the display device 10_3 through both the left and right eyes.

FIG. 4 is an exploded perspective view showing a display device 10 according to an embodiment of the present disclosure.

Referring to FIG. 4, the display device 10 according to the embodiment displays moving images or still images. The display device 10 according to the embodiment may be employed by portable electronic devices such as a mobile phone, a smart phone, a tablet PC, a mobile communications terminal, an electronic notebook, an electronic book, a portable multimedia player (PMP), a navigation device and a ultra mobile PC (UMPC). For example, the display device 10 may be used as a display unit of a television, a laptop computer, a monitor, an electronic billboard, or the Internet of Things (IoT). Alternatively, the display device 10 may be applied to a smart watch, a watch phone, or a head-mounted display (HMD) for implementing virtual reality and augmented reality.

According to the embodiment, the display device 10 includes a display panel 410, a heat dissipation layer 420, a circuit board 430, a driver circuit 440, and a power supply circuit 450.

The display panel 410 may have a shape similarly to a rectangular shape when viewed from the top. For example, the display panel 410 may have a shape similar to a rectangle having shorter sides in a first direction (x-axis direction) and longer sides in a second direction (y-axis direction) intersecting the first direction (x-axis direction) when viewed from the top. In the display panel 410, each of the corners where the shorter side in the first direction (x-axis direction) meets the longer side in the second direction (y-axis direction) may be rounded with a predetermined curvature or may be a right angle. The shape of the display panel 410 when viewed from the top is not limited to a rectangular shape, but may be formed in a shape similar to other polygonal shapes, a circular shape, or an elliptical shape. The shape of the display device 10 may follow the shape of the display panel 410 when viewed from the top, but the embodiments of the present disclosure are not limited thereto.

The display panel 410 includes a display area where images are displayed, and a non-display area where no image is displayed.

The display area includes a plurality of pixels, and each of the plurality of pixels includes a plurality of sub-pixels SP1, SP2 and SP3 (see FIG. 5). The sub-pixels SP1, SP2 and SP3 include a plurality of pixel transistors. The pixel transistors are formed via a semiconductor process and may be disposed on a semiconductor substrate SSUB (see FIG. 5). For example, the pixel transistors may be implemented as complementary metal oxide semiconductor (CMOS).

The heat dissipation layer 420 may overlap with the display panel 410 in the third direction (z-axis direction), which is the thickness direction of the display panel 410. The heat dissipation layer 420 may be disposed on one surface of the display panel 410, e.g., on the rear surface. The heat dissipation layer 420 serves to release heat generated in the display panel 410. The heat dissipation layer 420 may include a metal layer such as graphite, silver (Ag), copper (Cu) and aluminum (Al) having a high thermal conductivity.

The circuit board 430 may be electrically connected to a plurality of pads PD in a pad area PDA of the display panel 410 using a conductive adhesive member such as an anisotropic conductive film. The circuit board 430 may be a flexible printed circuit board made of a flexible material, or a flexible film. Although the circuit board 430 is unfolded in FIG. 4, the circuit board 430 may be bent. When it is bent, one end of the circuit board 430 may be disposed on the rear surface of the display panel 410. The one end of the circuit board 430 may be opposite to the opposite end of the circuit board 430, which is connected to the pads PD in the pad area PDA of the display panel 410 using a conductive adhesive member.

The driver circuit 440 may receive digital video data and timing signals from the outside. The driver circuit 440 may generate a scan timing control signal, an emission timing control signal, and a data timing control signal for controlling the display panel 410 in response to the timing signals.

A power supply circuit 450 may generate a plurality of panel driving voltages in response to a supply voltage from the outside.

Each of the driver circuit 440 and the power supply circuit 450 may be implemented as an integrated circuit (IC) and attached to a surface of the circuit board 430.

FIG. 5 is a cross-sectional view showing an example of a part of a display panel 410 according to an embodiment of the present disclosure. For example, FIG. 5 shows a cross-sectional structure of a part of a display area that includes a plurality of sub-pixels SP1, SP2 and SP3 (see FIG. 5).

Referring to FIG. 5, the display panel 410 includes a semiconductor backplane SBP, an emission material backplane EBP, an emission material layer EML, an encapsulation layer TFE, an optical layer OPL, and a cover layer CVL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE that are electrically connected to the pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well areas WA may be located in the upper surface of the semiconductor substrate SSUB. The well areas WA may be doped with second-type impurities. The second-type impurities may be different from the first-type impurities. For example, when the first-type impurities are p-type impurities, the second-type impurities may be n-type impurities. Alternatively, when the first-type impurities are n-type impurities, the second-type impurities may be p-type impurities.

The semiconductor substrate SSUB may be replaced with a glass substrate or a polymer resin substrate such as polyimide. In this instance, thin-film transistors may be disposed on a glass substrate or a polymer resin substrate. The glass substrate may be a rigid substrate that is not bent, while the polymer resin substrate may be a flexible substrate that can be bent or curved.

Each of the well areas WA includes a source region SA associated with a source electrode of a pixel transistor PTR, a drain region DA associated with a drain electrode thereof, and a channel region CH between the source region SA and the drain region DA.

Each of the source region SA and the drain region DA may be doped with the first-type impurities. The gate electrode GE of the pixel transistor PTR may overlap with the well area WA in the third direction (z-axis direction). The channel region CH may overlap with the gate electrode GE in the third direction (z-axis direction). The source area SA may be located on one side of the gate electrode GE, and the drain area SA may be located on the opposite side of the gate electrode GE.

A first semiconductor insulating film SINS1 may be disposed on the semiconductor substrate SSUB. The first semiconductor insulating film SINS1 may be formed of, but is not limited to, a silicon carbon nitride (SiCN) or a silicon oxide (SiOx)-based inorganic film.

A second semiconductor insulating film SINS2 may be disposed on the first semiconductor insulating film SINS1. The second semiconductor insulating film SINS2 may be formed of a silicon oxide (SiOx)-based inorganic film, but the embodiments of the present disclosure are not limited thereto.

A plurality of contact terminals CTE may be disposed on the second semiconductor insulating film SINS2. Each of the plurality of contact terminals CTE may be connected to one of the gate electrode GE, the region SA and the drain region DA of each of the pixel transistors PTR through a hole penetrating the first semiconductor insulating film SINS1 and the second semiconductor insulating film SINS2. The contact terminals CTE may be made of one of copper (Cu), aluminum (Al), tungsten (W), molybdenum (Mo), chromium (Cr), gold (Au), titanium (Ti), nickel (Ni) and neodymium (Nd), or an alloy containing one of these.

A third semiconductor insulating film SINS3 may be disposed on the side surface of each of the contact terminals CTE. The upper surface of each of the contact terminals CTE may not be covered by the third semiconductor insulating film SINS3 but may be exposed. The third semiconductor insulating film SINS3 may be formed of a silicon oxide (SiOx)-based inorganic film, but the embodiments of the present disclosure are not limited thereto.

The emission material backplane EBP includes first to eighth metal layers ML1 to ML8, reflective metal layers RL1 to RL4, a plurality of vias VA1 to VA10, and a step layer STPL. In addition, the emission material backplane EBP includes a plurality of interlayer dielectric films INS1 to INS10 disposed between the first to sixth metal layers ML1 to ML6.

The first to eighth metal layers ML1 to ML8 serve to implement a circuit of a sub-pixel SP by connecting a plurality of contact terminals CTE exposed from the semiconductor backplane SBP.

The first interlayer dielectric film INS1 may be disposed on the semiconductor backplane SBP. Each of the first vias VA1 may penetrate the first interlayer dielectric film INS1 and may be connected to the contact terminal CTE exposed from the semiconductor backplane SBP. Each of the first metal layers ML1 may be disposed on the first interlayer insulating film INS1 and may be connected to the first via VA1.

The second interlayer dielectric film INS2 may be disposed on the first interlayer dielectric film INS1 and the first metal layers ML1. Each of the second vias VA2 may penetrate through the second interlayer dielectric film INS2 to be connected to the exposed first metal layer ML1. Each of the second metal layers ML2 may be disposed on the second interlayer insulating film INS2 and may be connected to the second via VA2.

The third interlayer dielectric film INS3 may be disposed on the second interlayer dielectric film INS2 and the second metal layers ML2. Each of the third vias VA3 may penetrate through the third interlayer dielectric film INS3 to be connected to the exposed second metal layer ML2. Each of the third metal layers ML3 may be disposed on the third interlayer insulating film INS3 and may be connected to the third via VA3.

The fourth interlayer dielectric film INS4 may be disposed on the third interlayer dielectric film INS3 and the third metal layers ML3. Each of the fourth vias VA2 may penetrate through the fourth interlayer dielectric film INS4 to be connected to the exposed third metal layer ML3. Each of the fourth metal layers ML4 may be disposed on the fourth interlayer insulating film INS4 and may be connected to the fourth via VA4.

The fifth interlayer dielectric film INS5 may be disposed on the fourth interlayer dielectric film INS4 and the fourth metal layers ML4. Each of the fifth vias VA5 may penetrate through the fifth interlayer dielectric film INS5 to be connected to the exposed fourth metal layer ML4. Each of the fifth metal layers ML5 may be disposed on the fifth interlayer insulating film INS5 and may be connected to the fifth via VA5.

The sixth interlayer dielectric film INS6 may be disposed on the fifth interlayer dielectric film INS5 and the fifth metal layers ML5. Each of the sixth vias VA6 may penetrate through the sixth interlayer dielectric film INS6 to be connected to the exposed fifth metal layer ML5. Each of the sixth metal layers ML6 may be disposed on the sixth interlayer insulating film INS6 and may be connected to the sixth via VA6.

The seventh interlayer dielectric film INS7 may be disposed on the sixth interlayer dielectric film INS6 and the sixth metal layers ML6. Each of the seventh vias VA7 may penetrate through the seventh interlayer dielectric film INS7 to be connected to the exposed sixth metal layer ML6. Each of the seventh metal layers ML7 may be disposed on the seventh interlayer insulating film INS7 and may be connected to the seventh via VA7.

The eighth interlayer dielectric film INS8 may be disposed on the seventh interlayer dielectric film INS7 and the seventh metal layers ML7. Each of the eighth vias VA8 may penetrate through the eighth interlayer dielectric film INS8 to be connected to the exposed seventh metal layer ML7. Each of the eighth metal layers ML8 may be disposed on the eighth interlayer insulating film INS8 and may be connected to the eighth via VA8.

The first to eighth metal layers ML1 to ML8 and the first to eighth vias VA1 to VA8 may be made of substantially the same material. The first to eighth metal layers ML1 to ML8 and the first to eighth vias VA1 to VA8 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. The first to eighth vias VA1 to VA8 may be made of substantially the same material. The first to eighth interlayer dielectric films INS1 to INS8 may be formed of a silicon oxide (SiOx)-based inorganic film, but embodiments of the present specification are not limited thereto.

The thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6 may be greater than the thickness of the first via VA1, the thickness of the second via VA2, the thickness of the third via VA3, the thickness of the fourth via VA4, the thickness of the fifth via VA5 and the thickness of the sixth via VA6. The thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5 and the thickness of the sixth metal layer ML6 may be substantially all equal.

The thickness of the seventh metal layer ML7 and the thickness of the eighth metal layer ML8 may be greater than the thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6. The thickness of the seventh metal layer ML7 and the thickness of the eighth metal layer ML8 may be greater than the thickness of the seventh via VA7 and the thickness of the eighth via VA8. The thickness of the seventh via VA7 and the thickness of the eighth via VA8 may be greater than the thickness of the first via VA1, the thickness of the second via VA2, the thickness of the third via VA3, and the thickness of the fourth via VA4, the thickness of the fifth via VA5 and the thickness of the sixth via VA6. The thickness of the seventh metal layer ML7 may be substantially equal to the thickness of the eighth metal layer ML8.

The ninth interlayer dielectric film INS9 may be disposed on the eighth interlayer dielectric film INS8 and the eighth metal layers ML8. The ninth interlayer dielectric film INS9 may be formed of a silicon oxide (SiOx)-based inorganic film, but the embodiments of the present disclosure are not limited thereto.

Each of the ninth vias VA9 may penetrate through the ninth interlayer dielectric film INS9 to be connected to the exposed eighth metal layer ML8. The ninth vias VA9 may be made of one of copper (Cu), aluminum (Al), tungsten (W), molybdenum (Mo), chromium (Cr), gold (Au), titanium (Ti), nickel (Ni) and neodymium (Nd), or an alloy containing one of these.

The first reflective electrodes RL1 may be disposed on the ninth interlayer dielectric film INS9 and may be connected to the ninth via VA9. The first reflective electrodes RL1 may be made of one of copper (Cu), aluminum (Al), tungsten (W), molybdenum (Mo), chromium (Cr), gold (Au), titanium (Ti), nickel (Ni) and neodymium (Nd), or an alloy containing one of these.

The second reflective electrodes RL2 may be disposed on the first reflective electrodes RL1. The second reflective electrodes RL2 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. For example, the second reflective electrodes RL2 may be titanium nitride (TiN).

In the first sub-pixel SP1, a step layer STPL may be disposed on the second reflective electrode RL2. No step layer STPL may be disposed in each of the second sub-pixel SP2 and the third sub-pixel SP3. The thickness of the step layer STPL may be determined based on the wavelength of the light of a first color and the distance from a first emissive layer EML1 to a fourth reflective electrode RL4 so that the light of the first color emitted from the first emissive layer EML1 is advantageously reflected. The step layer STPL may be formed of, but is not limited to, a silicon carbon nitride (SiCN) or a silicon oxide (SiOx)-based inorganic film.

In the first sub-pixel SP1, the third reflective electrode RL3 may be disposed on the second reflective electrode RL2 and the step layer STPL. In the second sub-pixel SP2 and the third sub-pixel SP3, the third reflective electrode RL3 may be disposed on the second reflective electrode RL2. The third reflective electrodes RL3 may be made of one of copper (Cu), aluminum (Al), tungsten (W), molybdenum (Mo), chromium (Cr), gold (Au), titanium (Ti), nickel (Ni) and neodymium (Nd), or an alloy containing one of these.

At least one of the first reflective electrode RL1, the second reflective electrode RL2 and the third reflective electrode RL3 may be eliminated.

The fourth reflective electrodes RL4 may be disposed on the third reflective electrodes RL3. The fourth reflective electrodes RL4 may reflect lights from the first to third emissive layers EML1, EML2 and EML3. The fourth reflective electrodes RL4 may include a metal with high reflectivity to be advantageous for light reflection. The fourth reflective electrodes RL4 may be made up of, but is not limited to, aluminum (Al), a stack of aluminum and titanium (Ti/Al/Ti), a stack of aluminum and ITO (ITO/AI/ITO), silver (Ag), palladium (Pd), and an APC alloy, which is an alloy of copper (Cu), and a stack of an APC alloy and ITO (ITO/APC/ITO).

The tenth interlayer dielectric film INS10 may be disposed on the ninth interlayer dielectric film INS9 and the fourth reflective electrodes RL4. The tenth interlayer dielectric film INS10 may be formed of a silicon oxide (SiOx)-based inorganic film, but the embodiments of the present disclosure are not limited thereto.

Each of the tenth vias VA10 may penetrate through the tenth interlayer dielectric film INS10 to be connected to the exposed ninth metal layer ML9. The tenth vias VA10 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. Due to the step layer STPL, the thickness of the tenth via VA10 in the first sub-pixel SP1 may be smaller than the thickness of the tenth via VA10 in each of the second sub-pixel SP2 and the third sub-pixel SP3.

The emission material layer EML may be disposed on the emission material backplane EBP. The emission material layer EML may include light-emitting elements LE each including a first electrode AND, an intermediate layer IL and a second electrode CAT, and a pixel-defining layer PDL.

The first electrode AND may be disposed on the tenth interlayer dielectric film INS10 and may be connected to the tenth via VA10. The first electrode AND may be connected to the drain region DA or the source region SA of the pixel transistor PTR through the tenth via VA10, the first to fourth reflective electrodes RL1 to RL4, the first to ninth vias VA1 to VA9, the first to eighth metal layers ML1 to ML8 and the contact terminals CTE. The first electrode AND may be made of one of copper (Cu), aluminum (Al), tungsten (W), molybdenum (Mo), chromium (Cr), gold (Au), titanium (Ti), nickel (Ni) and neodymium (Nd), or an alloy containing one of these. For example, the first electrode AND may be titanium nitride (TiN).

The pixel-defining layer PDL may be disposed partially on the first electrode AND. The pixel-defining layer PDL may be disposed on edges of the first electrode AND. The pixel-defining layer PDL serves to partition the first emission areas EA1, the second emission areas EA2 and the third emission areas EA3.

A first emission area EA1 may be defined as an area in the first sub-pixel SP1 where the first electrode AND, the intermediate layer IL and the second electrode CAT are sequentially stacked on one another to emit light. A second emission area EA2 may be defined as an area in the second sub-pixel SP2 where the first electrode AND, the intermediate layer IL and the second electrode CAT are sequentially stacked on one another to emit light. A third emission area EA3 may be defined as an area in the third sub-pixel SP3 where the first electrode AND, the intermediate layer IL and the second electrode CAT are sequentially stacked on one another to emit light.

The pixel-defining layer PDL may include first to third pixel-defining layers PDL1, PDL2 and PDL3. The first pixel-defining layer PDL1 may be disposed on the edge of the first electrode AND, the second pixel-defining layer PDL2 may be disposed on the first pixel-defining layer PDL1, and the third pixel-defining layer PDL3 may be disposed on the second pixel-defining layer PDL2. The first pixel-defining layer PDL1, the second pixel-defining layer PDL2 and the third pixel-defining layer PDL3 may be formed of a silicon oxide (SiOx)-based inorganic film, but the embodiments of the present disclosure are not limited thereto.

The intermediate layer IL may include a first intermediate layer IL1, a second intermediate layer IL2, and a third intermediate layer IL3.

The intermediate layer IL may have a tandem structure including a plurality of intermediate layers IL1, IL2 and IL3 that emit different lights. For example, the intermediate layer IL may include the first intermediate layer IL1 that emits light of the first color, the second intermediate layer IL2 that emits light of the third color, and the third intermediate layer IL3 that emits light of the second color. The first intermediate layer IL1, the second intermediate layer IL2 and the third intermediate layer IL3 may be sequentially stacked on one another.

The first intermediate layer IL1 may have a structure in which a first hole transport layer, a first organic emissive layer that emits light of the first color, and a first electron transport layer are sequentially stacked on one another. The second intermediate layer IL2 may have a structure in which a second hole transport layer, a second organic emissive layer that emits light of the third color, and a second electron transport layer are sequentially stacked on one another. The third intermediate layer IL3 may have a structure in which a third hole transport layer, a third organic emissive layer that emits light of the second color, and a third electron transport layer are sequentially stacked on one another.

A plurality of intermediate layers IL arranged adjacent to each other in the first direction (x-axis direction) may be disconnected by the pixel-defining layer PDL. In the display panel 410 according to the embodiment, it is possible to prevent leakage current between adjacent sub-pixel SP1, SP2 and SP3 and to prevent color crosstalk by disconnecting the intermediate layers IL of the adjacent sub-pixel SP1, SP2 and SP3. The color crosstalk refers to, for example, a phenomenon that a red sub-pixel adjacent to a blue sub-pixel is unintentionally turned on while the blue sub-pixel emits blue light. Since color crosstalk occurs due to leakage current, it may occur if a blue sub-pixel and a red sub-pixel are adjacent to each other, which have a large difference in voltage for driving the sub-pixels. For example, while the driving current is supplied to the light-emitting element LEL of a blue sub-pixel in order to turn on the blue sub-pixel, a part of the driving current may be transmitted to a red sub-pixel through at least some conductive layers of the intermediate layer IL, which is leakage current. If leakage current is generated, the red sub-pixel may be unintentionally turned on while the blue sub-pixel is turned on.

The number of intermediate layers IL1, IL2 and IL3 emitting different lights is not limited to that shown in FIG. 5. For example, the intermediate layer IL may include two intermediate layers. In this instance, one of the two intermediate layers is substantially identical to the first intermediate layer IL1, and the other one may include a second hole transport layer, a second organic emissive layer, a third organic emissive layer, and a second electron transport layer. In this instance, a charge generation layer may be disposed between the two intermediate layers to supply electrons to one intermediate layer and to supply charges to the other intermediate layer.

Although the first to third intermediate layers IL1, IL2 and IL3 are all disposed in the first emission area EA1, the second emission area EA2 and the third emission area EA3 in FIG. 5, the embodiments of the present disclosure are not limited thereto. For example, the first intermediate layer IL1 may be disposed in the first emission area EA1 but not in the second emission area EA2 and the third emission area EA3. In addition, the second intermediate layer IL2 may be disposed in the second emission area EA2 but not in the first emission area EA1 and the third emission area EA3. In addition, the third intermediate layer IL3 may be disposed in the third emission area EA3 but not in the first emission area EA1 and the second emission area EA2. In this instance, the first to third color filters CF1, CF2 and CF3 of the optical layer OPL may be eliminated.

The second electrode CAT may be disposed on the third intermediate layer IL3. The second electrode CAT may be disposed on the third intermediate layer IL3 in each of a plurality of trenches TRC. The second electrode CAT may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the second electrode CAT is formed of a semi-transmissive conductive material, the light extraction efficiency can be increased by using microcavities in each of the first to third sub-pixels SP1, SP2 and SP3.

The encapsulation layer TFE may be disposed on the emission material layer EML. The encapsulation layer TFE may include one or more inorganic films TFE1 and TFE2 to prevent permeation of oxygen or moisture into the emission material layer EML. In addition, the encapsulation layer ENC may include at least one organic film to protect the emission material layer EML from particles such as dust. For example, the encapsulation layer ENC may include a first inorganic encapsulation film TFE1, an organic encapsulation film TFE2 and a second inorganic encapsulation film TFE3.

The first inorganic encapsulation film TFE1 may be disposed on the second electrode CAT, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer (SiNx), a silicon oxynitride layer (SiON), a silicon oxide layer (SiOx), a titanium oxide layer (TiOx) and an aluminum oxide layer (AlOx) are alternately stacked on one another. The organic encapsulation film TFE2 may be a monomer. Alternatively, the organic encapsulation film TFE2 may be an organic film such as an acryl resin, an epoxy resin, a phenolic resin, a polyamide resin, a polyimide resin, etc.

An adhesive layer ADL may adhere the encapsulation layer TFE to the optical layer OPL. The adhesive layer ADL may be a double-sided adhesive member. In addition, the adhesive layer ADL may be a transparent adhesive member such as a transparent adhesive and a transparent adhesive resin.

The optical layer OPL includes a plurality of color filters CF1, CF2 and CF3, a plurality of lenses LNS, and a filling layer FIL. The plurality of color filters CF1, CF2 and CF3 may include first to third color filters CF1, CF2 and CF3. The first to third color filters CF1, CF2 and CF3 may be disposed on the adhesive layer ADL.

The first color filter CF1 may be in line with the first emission area EA1 of the first sub-pixel SP1. The first color filter CF1 may transmit light of the first color, i.e., light in the blue wavelength range. The blue wavelength range may be approximately 370 nm to 460 nm. Therefore, the first color filter CF1 may transmit light of the first color among the lights emitted from the first emission area EA1.

The second color filter CF2 may be in line with the second emission area EA2 of the second sub-pixel SP2. The second color filter CF2 may transmit light of the second color, i.e., light in the green wavelength range. The green wavelength range may be approximately 480 nm to 560 nm. Therefore, the second color filter CF2 may transmit light of the second color among the lights emitted from the second emission area EA2.

The third color filter CF3 may be in line with the third emission area EA3 of the third sub-pixel SP3. The third color filter CF3 may transmit light of the third color, i.e., light in the red wavelength range. The blue wavelength range may be approximately 600 nm to 750 nm. Therefore, the third color filter CF3 may transmit light of the third color among the lights emitted from the third emission area EA3.

The lenses LNS may be disposed on the first color filter CF1, the second color filter CF2 and the third color filter CF3, respectively. Each of the lenses LNS may be a structure for increasing the ratio of light directed to the front side of the display device 10. Each of the lenses LNS may have a cross-sectional shape that is convex upward.

The filling layer FIL may be disposed on a plurality of lenses LNS. The filling layer FIL may have a predetermined refractive index so that light travels in the third direction (z-axis direction) at the interface between the plurality of lenses LNS and the filling layer FIL. In addition, the filling layer FIL may be a planarization layer. The filling layer FIL may be an organic film such as an acryl resin, an epoxy resin, a phenolic resin, a polyamide resin, and a polyimide resin.

The cover layer CVL may be disposed on the filling layer FIL. The cover layer CVL may be a glass substrate or a polymer resin such as a resin. If the cover layer CVL is a glass substrate, it may be attached to the filling layer FIL. In this instance, the filling layer FIL may adhere the cover layer CVL. If the cover layer CVL is a glass substrate, it may work as an encapsulation substrate. If the cover layer CVL is a polymer resin such as a resin, it may be applied directly on the filling layer FIL.

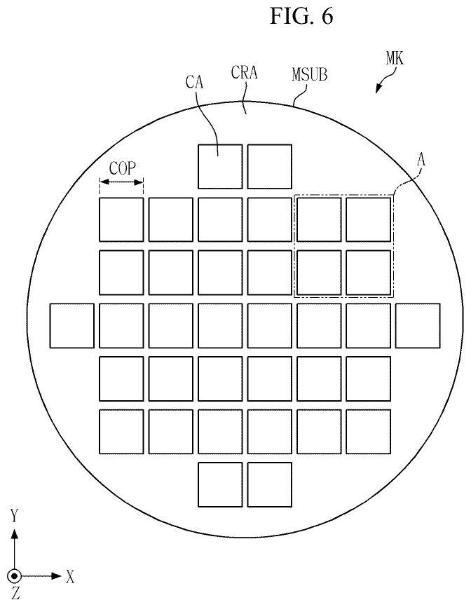

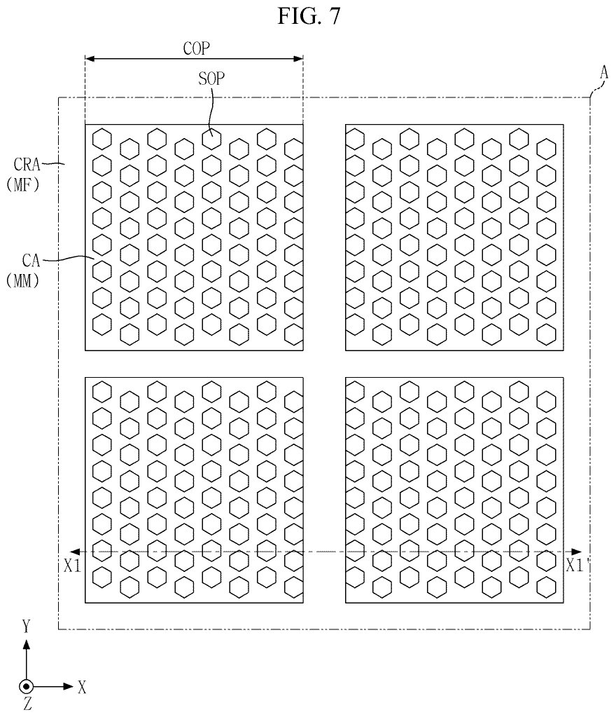

FIG. 6 is a plan view of a mask MK according to an embodiment. FIG. 7 is an enlarged plan view of area A of FIG. 6. The mask MK according to the embodiment shown in FIG. 6 may be used in a process of depositing at least a part of the intermediate layer IL of the display panel 410 described above with reference to FIG. 5.

Referring to FIGS. 6 and 7, the mask MK according to the embodiment may be a mask used to fabricate ultra-high resolution displays. For example, the mask MK may be a mask used to fabricate a display included in extended reality devices (XR devices) such as a VR device, an AR device and an MR device.

The mask MK according to the embodiment may be used to perform a deposition process of sub-pixels (the sub-pixels SP1, SP2 SP3 in FIG. 5) on a silicon wafer rather than a large-area substrate used for existing displays. For a display included in an extended reality device, the screen is located directly in front of the user's eyes, and thus it can have a small screen rather than a large one. In addition, because it is located close to the user's eyes, ultra-high resolution may be required. For example, the required resolution of a display included in an extended reality device may be approximately 1,000 PPI or more, and preferably, an ultra-high resolution of 2,000 PPI or more. Accordingly, the deposition mask MK according to the embodiment may be a mask used to fabricate such ultra-high resolution displays.

The mask MK according to the embodiment may include a mask substrate MSUB.

The mask substrate MSUB according to the embodiment may include a silicon wafer. Silicon wafers may be used as substrates for ultra-high resolution displays because they allow finer and more precise processing by utilizing the technologies developed in semiconductor processing than large-area substrates. The mask MK according to the embodiment may use a silicon wafer in the same manner to form pixels on the silicon wafer of such an ultra-high resolution display.

The shape of the mask substrate MSUB according to the embodiment may conform to a silicon wafer of an ultra-high resolution display. For example, the mask substrate MSUB may have the same size or shape as the silicon wafer of the ultra-high resolution display. It should be understood, however, that the embodiments of the present disclosure are not limited thereto. The mask substrate MSUB may include a large-area substrate. For example, the mask substrate MSUB may include a material such as glass, quartz and polymer resin.

The mask substrate MSUB according to the embodiment may include a plurality of cell areas CA and a cell peripheral area CRA.

The cell peripheral area CRA according to the embodiment may surround the plurality of cell areas CA. The cell peripheral area CRA may be in line with a mask frame MF. The mask frame MF may define mask openings COP when viewed from the top, and the mask frame MF may surround the mask openings COP. The mask frame MF may be an area that supports the mask MK. The structure of the mask frame MF will be described later.

According to the embodiment of the present disclosure, a plurality of cell areas CA may be formed, and the cell areas CA may be spaced apart from one another. The cell areas CA may be located in line with the mask openings COP. In other words, the cell areas CA may not overlap with the mask frame MF. According to the embodiment, the cell areas CA may overlap with a mask membrane MM. The mask membrane MM may include a plurality of patterns and pixel opening SOP when viewed from the top. The plurality of patterns included in the mask membrane MM may be formed as one body, surrounding the pixel openings SOP when viewed from the top. The plurality of patterns included in the mask membrane MM may entirely surround the pixel openings SOP when viewed from the top, and the mask frame MF may entirely surround the plurality of patterns included in the mask membrane MM when viewed from the top. The plurality of patterns included in the mask membrane MM will be described later.

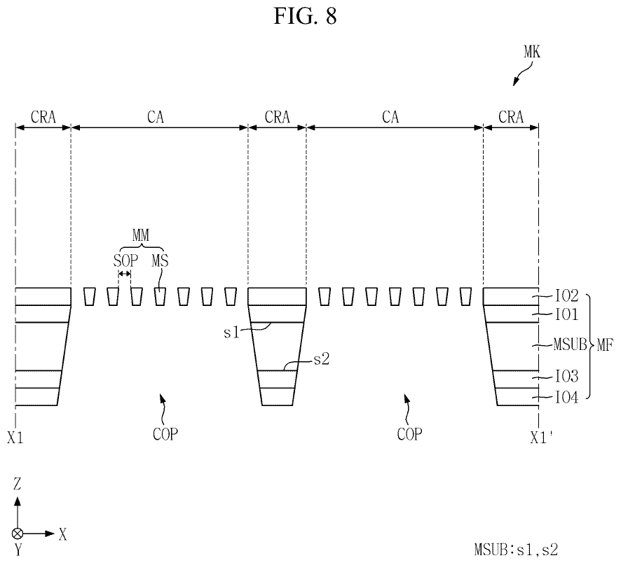

FIG. 8 is a cross-sectional view taken along line X1-X1′ of FIG. 7.

Referring to FIG. 8, the mask frame MF according to the embodiment may include a mask substrate MSUB and first to fourth mask inorganic layers IO1, 102, 103 and IO4. The first mask inorganic layer IO1 and the second mask inorganic layer IO2 may be located on an upper surface s1 of the mask substrate MSUB, and the third mask inorganic layer IO3 and the fourth mask inorganic layer 104 may be located on a lower surface s2 of the mask substrate MSUB. The mask substrate MSUB has been described above; and, therefore, the redundant descriptions will be omitted.

According to the embodiment of the present disclosure, the first mask inorganic layer IO1 may be located on the upper surface s1 of the mask substrate MSUB and may be in contact with the upper surface s1. The first mask inorganic layer IO1 may include an inorganic insulating material. For example, the first mask inorganic layer IO1 may include one of silicon nitride, silicon oxide, and silicon oxynitride.

According to the embodiment of the present disclosure, the second mask inorganic layer 102 may be located on the first mask inorganic layer IO1 and may be in contact with the first mask inorganic layer IO1. According to the embodiment of the present disclosure, the second mask inorganic layer IO2 may include the same material as mask shadows MS of the mask membrane MM, which will be described later. In the process of fabricating the mask MK according to the embodiment of the present disclosure, the mask shadows MS and the second mask inorganic layer IO2 may be formed as one body and then formed into the shape shown via an etching process. The fabrication process will be described later.

The second mask inorganic layer IO2 according to the embodiment may include an inorganic insulating material. For example, the second mask inorganic layer IO2 may include one of silicon nitride, silicon oxide, and silicon oxynitride. According to an embodiment of the present disclosure, the first mask inorganic layer IO1 and the second mask inorganic layer IO2 may include different materials. For example, when the first mask inorganic layer IO1 is silicon oxide, the second mask inorganic layer 102 may include either silicon nitride or silicon oxynitride excluding silicon oxide.

The mask MK according to the embodiment is formed by stacking the first mask inorganic layer IO1 and the second mask inorganic layer IO2 including different inorganic materials, so that stress properties of each of the first mask inorganic layer IO1 and the second mask inorganic layer IO2 can be reduced. For example, the stacked structure may be designed such that if the first mask inorganic layer IO1 is formed of silicon oxide having compressive stress, the second mask inorganic layer IO2 is formed of silicon nitride having tensile stress. Accordingly, the mask frame MF according to the embodiment can prevent delamination between the first mask inorganic mask IO1 and the second mask inorganic layer IO2.

According to the embodiment of the present disclosure, the third mask inorganic layer IO3 may be located on the lower surface s2 of the mask substrate MSUB and may be in contact with the lower surface s2 of the mask substrate MSUB. The third mask inorganic layer IO3 may be formed via the same process as the first mask inorganic layer IO1. Accordingly, the third mask inorganic layer IO3 may include the same material as the first mask inorganic layer IO1. The fabrication process will be described later.

According to the embodiment of the present disclosure, the fourth mask inorganic layer 104 may be located on the third mask inorganic layer IO3 and may be in contact with the third mask inorganic layer IO3. The fourth mask inorganic layer 104 may be formed via the same process as the second mask inorganic layer IO2, and accordingly the fourth mask inorganic layer 104 may include the same material as the second mask inorganic layer IO2. The fabrication process will be described later.

According to the embodiment, the mask frame MF may define mask openings COP. The plurality of mask openings COP may be created by etching portions of the mask substrate MSUB from the lower surface s2 of the mask substrate MSUB.

According to the embodiment, the mask membrane MM may be located in line with the cell areas CA. The cell areas CA may be defined by the mask openings COP.

According to the embodiment, the mask membrane MM may include a plurality of mask shadows MS, and adjacent ones of the mask shadows MS may define a pixel opening SOP. That is to say, the mask membrane MM may include a plurality of mask shadows MS and pixel openings SOP.

The pixel openings SOP of the mask membrane MM may be referred to as holes or mask holes. The plurality of pixel openings SOP may penetrate the mask frame MF along the thickness direction of the mask MK (e.g., third direction (z-axis direction)). The plurality of pixel openings SOP may be created by etching portions of the mask substrate MSUB from the lower surface s2 of the mask substrate MSUB.

The mask shadows MS can work as a blocking unit that masks a substrate subjected to deposition (e.g., the display panel 410, or backplane substrate) when a deposition material evaporates from a deposition source inside a deposition apparatus. Accordingly, the deposition material generated from the deposition source may be deposited on a surface of the substrate subjected to deposition (e.g., the display panel 410 or backplane substrate) through the pixel openings SOP of the mask membrane MM.

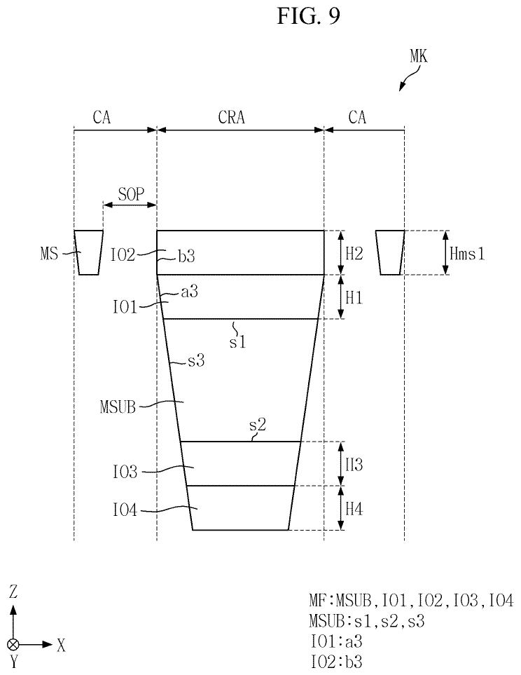

FIG. 9 is an enlarged cross-sectional view of the mask frame MF and structures around the mask frame MF of FIG. 8.

Referring to FIG. 9, the mask substrate MSUB according to the embodiment may include a side surface s3 facing a cell area CA. The side surface s3 of the mask substrate MSUB may face a pixel opening SOP and may connect the upper surface s1 with the lower surface s2.

In some embodiments, the first mask inorganic layer IO1 may include a side surface a3 facing the cell area CA. The side surface a3 of the first mask inorganic layer IO1 may face the pixel opening SOP. According to the embodiment of the present disclosure, the side surface a3 of the first mask inorganic layer IO1 may be extended from the side surface s3 of the mask substrate MSUB. In other words, the side surface a3 of the first mask inorganic layer IO1 does not protrude from the side surface s3 of the mask substrate MSUB and may be located on the same line extended from the side surface s3 of the mask substrate MSUB. It should be noted that there may be an error in the range of 1 micro or less due to process errors.

In some embodiments, the second mask inorganic layer IO2 may include a side surface b3 facing the cell area CA. The side surface b3 of the second mask inorganic layer IO2 may face the pixel opening SOP. The side surface b3 of the second mask inorganic layer IO2 may be spaced apart from the mask shadows MS with the pixel opening SOP therebetween. In other words, the second mask inorganic layer IO2 may be spaced apart from the mask shadows MS with a space therebetween.

In some embodiments, the side surface b3 of the second mask inorganic layer IO2 may be extended from the side surface a3 of the first mask inorganic layer IO1. In other words, the side surface b3 of the second mask inorganic layer IO2 may not protrude from the side surface a3 of the first mask inorganic layer IO1 and may be located on the same line extended therefrom.

In other words, the side surface b3 of the second mask inorganic layer IO2 according to the embodiment may be located on the same line extended from the side surface s3 of the mask substrate MSUB. The side surface b3 of the second mask inorganic layer IO2 does not protrude from the side surface s3 of the mask substrate MSUB and may be patterned such that it is aligned with the line extended from the edge of the mask substrate MSUB. It should be noted that there may be an error in the range of 1 micro or less due to process errors.

According to the embodiment of the present disclosure, the first mask inorganic layer IO1 and the second mask inorganic layer IO2 are patterned such that they are aligned with the line extended from the edge of the mask substrate MSUB of the mask MK, the first mask inorganic layer IO1 and the second mask inorganic layer IO2 may be formed entirely in contact with the mask substrate MSUB without any protrusions. Therefore, the mask MK according to the embodiment can solve the issue of warpage of the mask inorganic layer, and as a result, the mask MK according to the embodiment can increase the adhesion between the ultra-high resolution display panel 410 and the mask MK.

In some embodiments, the height H1 of the first mask inorganic layer IO1 may be equal to the height H3 of the third mask inorganic layer IO3. This may be because the first mask inorganic layer IO1 and the third mask inorganic layer IO3 are formed via the same process.

In addition, the height H2 of the second mask inorganic layer IO2 may be equal to the height H4 of the fourth mask inorganic layer IO4. This may be because the second mask inorganic layer IO2 and the fourth mask inorganic layer IO4 are formed via the same process. In addition, the height H2 of the second mask inorganic layer 102 may be equal to the height Hms1 of the mask shadows MS. This may be because the second mask inorganic layer IO2 and the mask shadows MS are formed via the same process. The fabrication process will be described later.

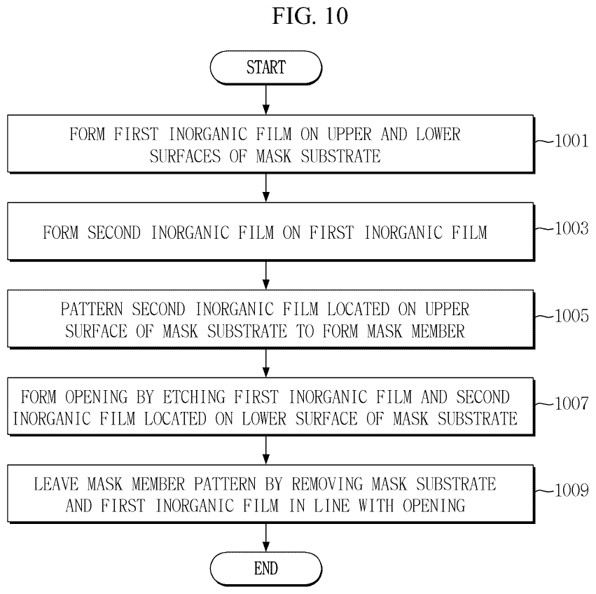

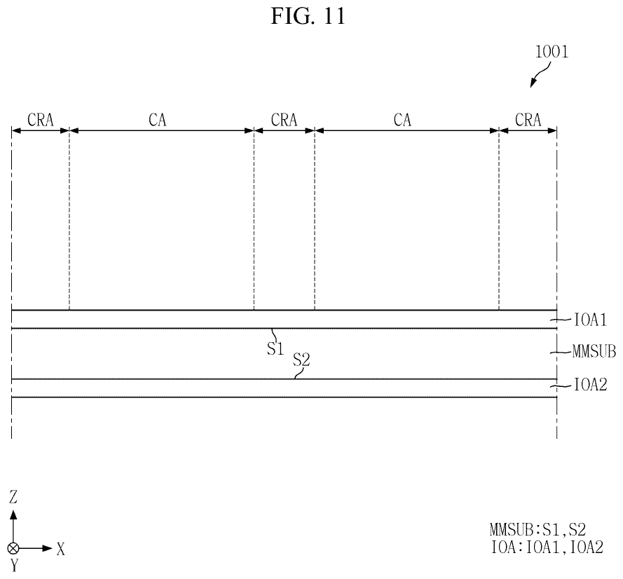

FIG. 10 is a flowchart for illustrating a method for fabricating a mask MK according to an embodiment. FIGS. 11 to 20 are cross-sectional views for illustrating processing steps of the method for fabricating a mask MK according to the embodiment of the present disclosure.

Hereinafter, the method for fabricating a mask MK according to the embodiment will be described with reference to FIGS. 10 to 20. It should be noted that only some of fabrication processes of the mask MK will be described. Other processes for forming the elements described herein may be additionally performed before or after the fabrication processes described below. In addition, fabrication processes of masks MK known in the art may be additionally performed before or after the fabrication processes described below.

Initially, referring to step 1001 of FIG. 10, forming first inorganic films on upper and lower surfaces of a mask substrate will be described.

Referring to FIG. 11, a mask mother substrate MMSUB including a plurality of cell areas CA and a cell peripheral area CRA is prepared. The cell peripheral area CRA may be the remaining area except the plurality of cell areas CA. The mask mother substrate MMSUB may include a silicon wafer.

Subsequently, a first inorganic material layer IOA is deposited on an upper surface S1 and a lower surface S2 of the mask mother substrate MMSUB. In this process, the mask mother substrate MMSUB is put into a slit to form the first inorganic material layer IOA. Accordingly, the first inorganic material layer IOA may be formed simultaneously on the upper surface S1 and the lower surface S2 of the mask mother substrate MMSUB. The first inorganic material layer IOA may be formed to entirely cover the upper surface S1 and the lower surface S2 of the mask mother substrate MMSUB.

In the following description, the first inorganic material layer IOA deposited on the upper surface S1 of the mask mother substrate MMSUB is referred to as a first upper surface material layer IOA1, and the first inorganic material layer IOA deposited on the lower surface S2 of the mask mother substrate MMSUB is referred to as a first lower surface material layer IOA2. As described above, the first inorganic material layer IOA may include an inorganic insulating material. The redundant descriptions will be omitted.

Subsequently, referring to step 1003 of FIG. 10, forming a second inorganic film on the first inorganic film will be described.

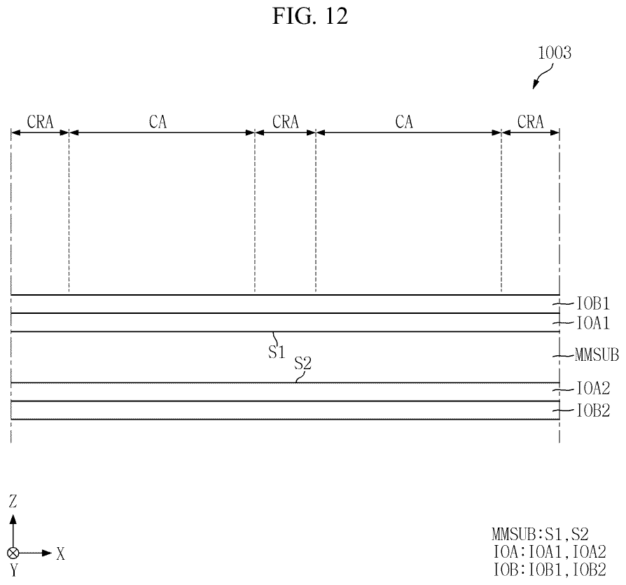

Referring to FIG. 12, a second inorganic material layer IOB is deposited on the first inorganic material layer IOA. In this process, similar to the forming the first inorganic material layer IOA, the second inorganic material layer IOB may be formed by putting the mask mother substrate MMSUB into the slit. Accordingly, the second inorganic material layer IOB may be formed simultaneously on the first upper surface material layer IOA1 and the first lower surface material layer IOA2 of the mask mother substrate MMSUB. The second inorganic material layer IOB may entirely cover the first upper surface material layer IOA1 and the first lower surface material layer IOA2. In the following description, the second inorganic material layer IOB deposited on the first upper surface material layer IOA1 is referred to as a second upper surface material layer IOB1, and the second inorganic material layer IOB deposited on the first lower surface material layer IOA2 is referred to as a second lower surface material layer IOB2.

As described above, the second inorganic material layer IOB may include an inorganic insulating material, and may include a different material from the first inorganic material layer IOA. The redundant descriptions will be omitted.

Subsequently, referring to step 1005 of FIG. 10, forming a mask membrane by patterning the second inorganic film located on the upper surface of the mask substrate will be described.

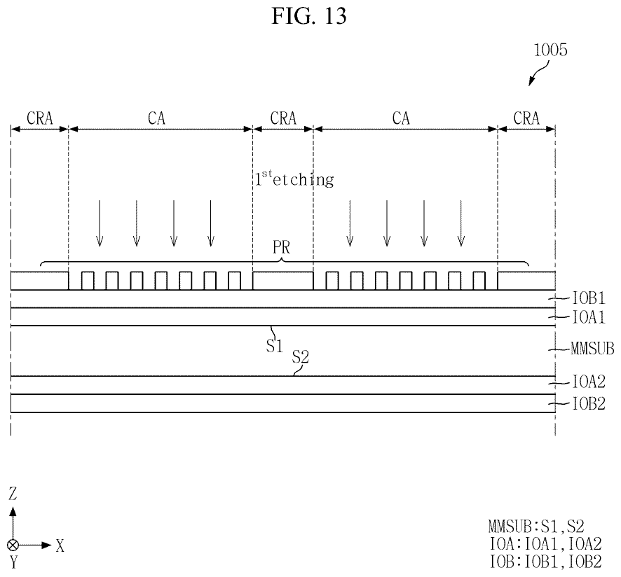

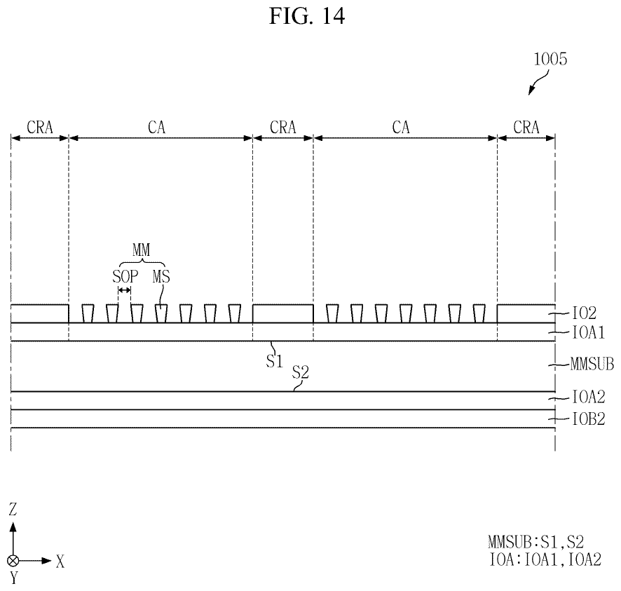

Referring to FIGS. 13 and 14, a plurality of photoresists PR is formed on the second inorganic material layer IOB, e.g., the second upper surface material layer IOB1, located on the upper surface S1 of the mask mother substrate MMSUB. In this process, the photoresists PR may be located in the cell areas CA and the cell peripheral area CRA. The photoresists PR located in the cell peripheral area CRA may entirely cover the second upper surface material layer IOB1, while the photoresists PR located in the cell areas CA may be spaced apart from one another.

Subsequently, a first etching process (1^{st} etching) is performed using a plurality of photoresists PR as a mask. For example, the first etching process (1^{st} etching) may be performed as a dry etching process. In this process, portions of the second upper surface material layer IOB1 located where the photoresists PR are not formed may be removed, and the second upper surface material layer IOB1 may be formed into the mask shadows MS and the second mask inorganic layer IO2 shown in FIG. 8. The mask shadows MS and the second mask inorganic layer IO2 may be spaced apart from each other in the first direction (x-axis direction) with the pixel opening SOP therebetween. The mask shadows MS formed in this process may surround the pixel openings SOP and may be spaced apart from one another.

Subsequently, referring to step 1007 of FIG. 10, forming openings by etching the first inorganic film and the second inorganic film located on the lower surface of the mask substrate will be described.

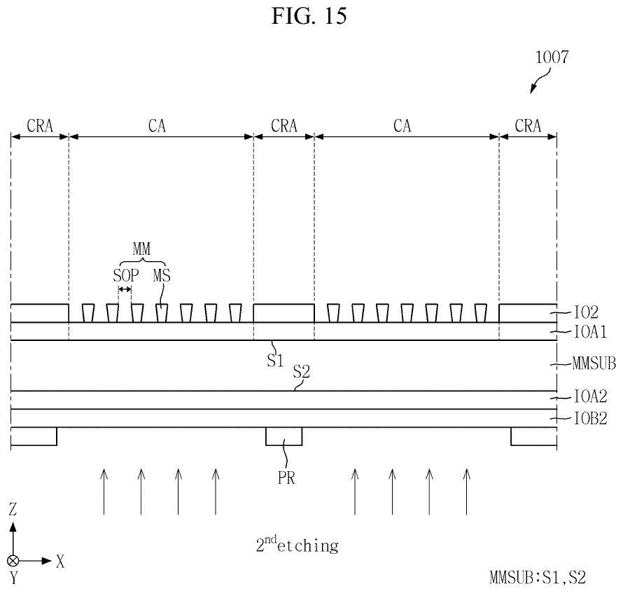

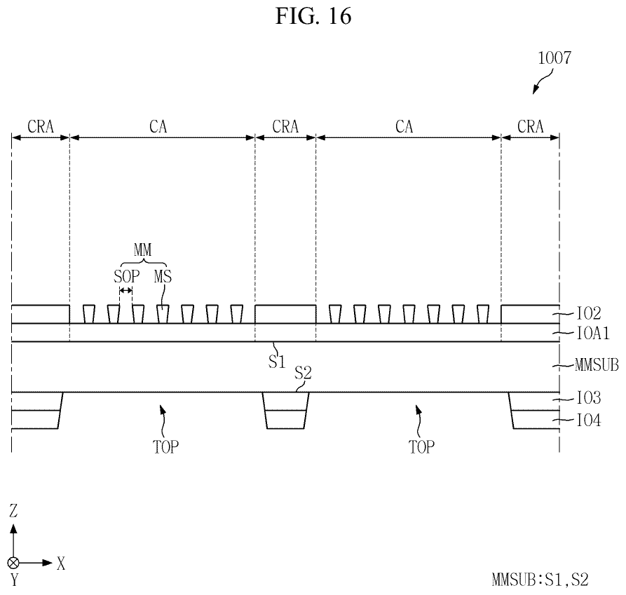

Referring to FIGS. 15 and 16, initially, a plurality of photoresists PR is formed on the second inorganic material layer IOB, e.g., the second lower surface material layer IOB2, located on the lower surface S2 of the mask mother substrate MMSUB. In this process, the photoresists PR may be located only in the cell peripheral area CRA.

Subsequently, a second etching process (2^{nd} etching) is performed using the plurality of photoresists PR as a mask. The second etching process (2^{nd} etching) may be performed toward the lower surface S2 of the mask mother substrate MMSUB, i.e., toward the rear surface of the mask mother substrate MMSUB. For example, the second etching process (2^{nd} etching) may be performed as a dry etching process.

In this process, portions of the first lower surface inorganic layer IOA2 and the second lower surface inorganic layer IOB2 located where the photoresists PR are not formed may be removed. In this process, temporary openings TOP may be formed where the first lower surface inorganic layer IOA2 and the second lower surface inorganic layer IOB2 have been removed. The temporary openings TOP may be in line with the cell areas CA. In this manner, the first lower surface inorganic layer IOA2 and the second lower surface layer IOB2 may be formed in the form of the third mask inorganic layer IO3 and the fourth mask inorganic layer IO4 shown in FIG. 8. The third mask inorganic layer IO3 and the fourth mask inorganic layer 104 may be located such that they overlap with the cell peripheral area CRA but not with the cell areas CA.

Subsequently, referring to step 1009 of FIG. 10, leaving a mask membrane pattern by removing the mask substrate and the first inorganic layer in line with the openings will be described.

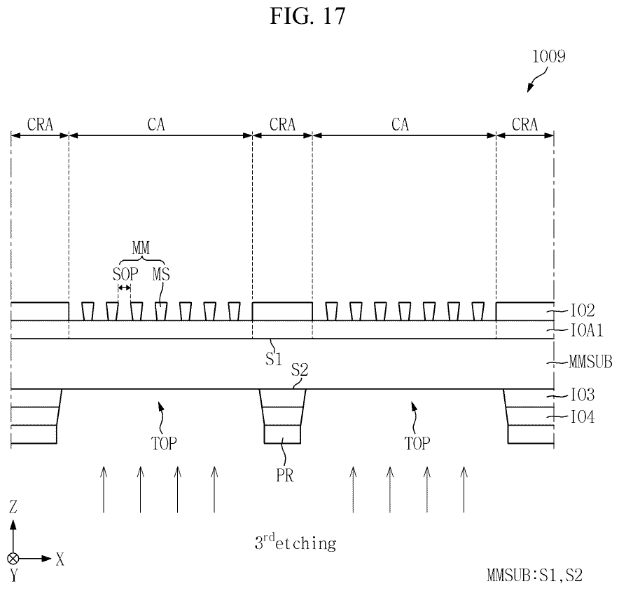

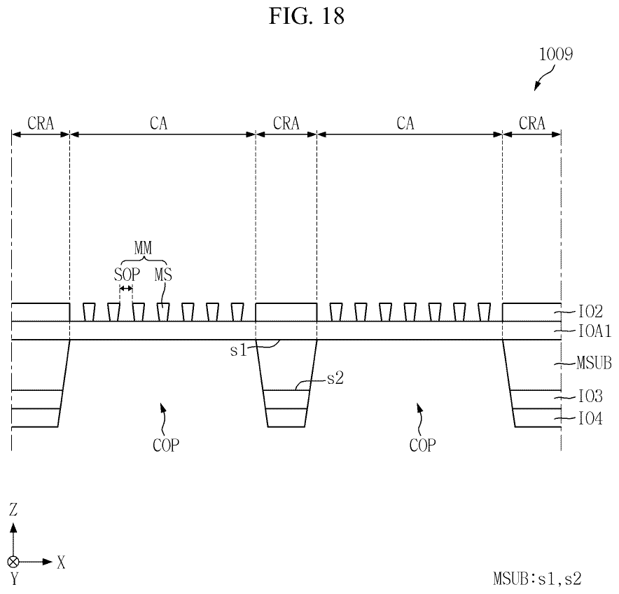

Referring to FIGS. 17 and 18, initially, a plurality of photoresists PR is formed on the fourth mask inorganic layer IO4 located in line with the cell peripheral area CRA. The photoresists PR may surround the temporary openings TOP.

Subsequently, a third etching process (3^{rd} etching) is performed using a plurality of photoresists PR as a mask. The third etching process (3^{rd} etching) may be performed toward the lower surface S2 of the mask mother substrate MMSUB, i.e., toward the rear surface of the mask mother substrate MMSUB. For example, the third etching process (3^{rd} etching) may be performed as a wet etching process. In this process, portions of the mask mother substrate MMSUB located where the photoresists PR are not formed may be removed. In other words, portions of the mask mother substrate MMSUB in line with the temporary openings TOP may be removed.

In this process, the mask mother substrate MMSUB may be formed into the shape of the mask substrate MSUB shown in FIG. 8, and the mask substrate MSUB may define the mask openings COP. The mask substrate MSUB may be located such that it overlaps with the cell peripheral area CRA but not with the cell areas CA. The mask substrate MSUB may include an upper surface s1 and a lower surface s2 in line with the cell peripheral area CRA.

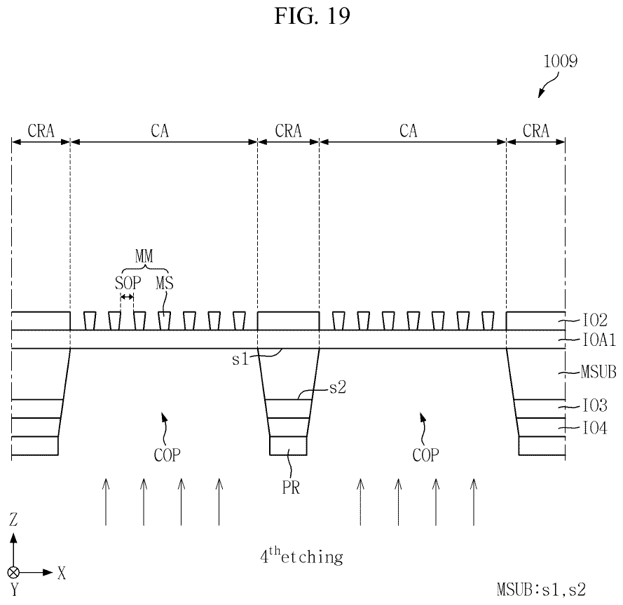

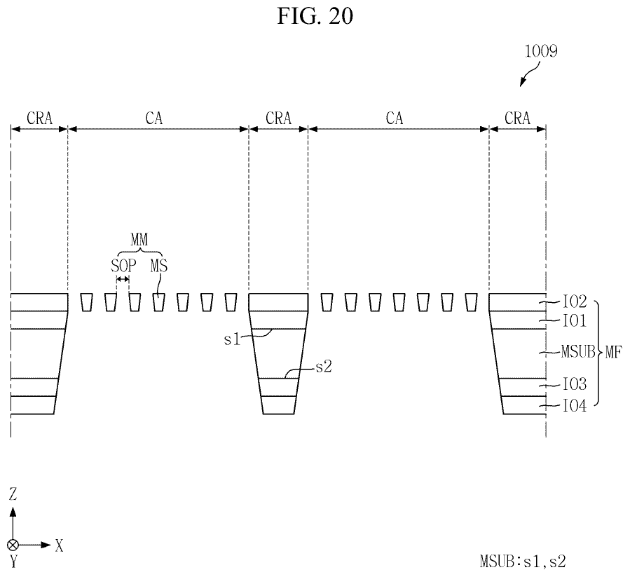

Referring to FIGS. 19 and 20, initially, a plurality of photoresists PR is formed on the fourth mask inorganic layer IO4 located in line with the cell peripheral area CRA. The photoresists PR may surround the mask openings COP.

Subsequently, a fourth etching process (4^{th} etching) is performed using a plurality of photoresists PR as a mask. The fourth etching process (4^{th} etching) may be performed toward the lower surface S2 of the mask mother substrate MMSUB, i.e., toward the rear surface of the mask mother substrate MMSUB. For example, the fourth etching process (4^{th} etching) may be performed as a wet etching process. In this process, the first upper surface inorganic layer IOA1 located where the photoresists PR are not formed may be removed. In other words, the first upper surface inorganic layer IOA1 in line with the mask openings COP may be removed.

In this process, the first upper surface inorganic layer IOA1 may be formed into the first mask inorganic layer IO1 shown in FIG. 8. The first mask inorganic layer IO1 may be located such that it overlaps with the cell peripheral area CRA but not with the cell areas CA. In this manner, the mask frame MF and mask membrane MM shown in FIG. 8 can be formed.

In this process, the pixel openings SOP may be formed such that they penetrate the mask frame MF as shown in FIG. 8. As described above, the pixel openings SOP included in the mask MK may be formed such that they overlap with the intermediate layer IL of the plurality of pixels SP shown in FIG. 5. Accordingly, the mask MK according to the embodiment can be used to fabricate the high-resolution display panel 410.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate comprising a plurality of cell areas and a cell peripheral area surrounding the plurality of cell areas;
a mask membrane overlapping with the cell areas of the mask substrate; and
a mask frame overlapping with the cell peripheral area of the mask substrate,
wherein the mask membrane comprises a mask shadow defining a pixel opening,
wherein the mask frame comprises a first mask inorganic layer on the mask substrate, and a second mask inorganic layer on the first mask inorganic layer, and
wherein the first mask inorganic layer and the second mask inorganic layer are formed in a certain pattern up to an edge of the mask substrate.

2. The deposition mask of claim 1, wherein the first mask inorganic layer and the second mask inorganic layer do not overlap with the cell areas, and
wherein the second mask inorganic layer comprises a same material as the mask shadow.

3. The deposition mask of claim 2, wherein the pixel opening is a through hole, and
wherein the second mask inorganic layer is spaced apart from the mask shadow with the pixel opening therebetween.

4. The deposition mask of claim 3, wherein the mask substrate comprises silicon, and wherein the mask substrate has a circular shape when viewed from top.

5. The deposition mask of claim 4, wherein the first mask inorganic layer and the second mask inorganic layer comprise an inorganic insulating material, and
wherein the first mask inorganic layer and the second mask inorganic layer comprise different materials.

6. The deposition mask of claim 1, wherein the first mask inorganic layer comprises silicon oxide, and the second mask inorganic layer comprises silicon nitride.

7. The deposition mask of claim 1, wherein the mask frame comprises:
a third mask inorganic layer located on the mask substrate on an opposite side of the first mask inorganic layer; and
a fourth mask inorganic layer located on the third mask inorganic layer.

8. The deposition mask of claim 7, wherein the third mask inorganic layer is made of a same material as the first mask inorganic layer, and the fourth mask inorganic layer is made of a same material as the second mask inorganic layer.

9. The deposition mask of claim 8, wherein a height of the first mask inorganic layer is equal to a height of the third mask inorganic layer, and a height of the second mask inorganic layer is equal to a height of the fourth mask inorganic layer.

10. The deposition mask of claim 1, wherein the mask substrate comprises a first side surface facing the cell area,
wherein the first mask inorganic layer comprises a second side surface facing the cell area, and
wherein the first side surface and the second side surface are located on a same line.

11. The deposition mask of claim 10, wherein the second mask inorganic layer comprises a third side surface facing the cell area, and the third side surface is located on the same line as the first side surface and the second side surface.

12. The deposition mask of claim 11, wherein the third side surface is spaced apart from the mask shadow with the pixel opening therebetween.

13. The deposition mask of claim 11, wherein the second side surface is located between the first side surface and the third side surface.

14. The deposition mask of claim 1, wherein the mask frame defines a mask opening when viewed from top,
wherein the membrane overlaps with the mask opening when viewed from the top, and
wherein the mask frame completely surrounds the membrane when viewed from the top.

15. A method for fabricating a deposition mask, the method comprising:
forming a first inorganic material layer on a mask substrate comprising a plurality of cell areas and a cell peripheral area surrounding the plurality of cell areas;
forming a second inorganic material layer on the first inorganic material layer;
forming a mask membrane by patterning the second inorganic material layer located on an upper surface of the mask substrate;
forming a mask opening by removing the first inorganic material layer and the second inorganic material layer located on a lower surface of the mask substrate; and
removing a portion of the mask substrate overlapping with the mask opening and the first inorganic material layer located on the upper surface of the mask substrate.

16. The method of claim 15, wherein the forming the first inorganic material layer comprises: forming the first inorganic material layer simultaneously on the upper and lower surfaces of the mask substrate.

17. The method of claim 16, wherein the forming the second inorganic material layer comprises: forming the second inorganic material layer simultaneously on the upper and lower surfaces of the mask substrate.

18. The method of claim 17, wherein the first inorganic material layer and the second inorganic material layer comprise different materials.

19. The method of claim 15, wherein a side surface of the first inorganic material layer and a side surface of the second inorganic material layer are located on a same line extended from a side surface of the patterned mask substrate.

20. The method of claim 15, wherein the first inorganic material layer and the second inorganic material layer are patterned up to an edge of the mask substrate.

21. An electronic device comprising:
A display device including a display panel formed using a deposition mask;
a mask substrate comprising a plurality of cell areas and a cell peripheral area surrounding the plurality of cell areas;
a mask membrane overlapping with the cell areas of the mask substrate; and
a mask frame overlapping with the cell peripheral area of the mask substrate,
wherein the mask membrane comprises a mask shadow defining a pixel opening,
wherein the mask frame comprises a first mask inorganic layer on the mask substrate, and a second mask inorganic layer on the first mask inorganic layer, and
wherein the first mask inorganic layer and the second mask inorganic layer are formed in a certain pattern up to an edge of the mask substrate.
